(19) United States
(12) Patent Application Publication
(10) Pub. No.: US 2026/0005072 A1
(43) Pub. Date: Jan. 1, 2026

(54) SUBSTRATE PROCESSING SYSTEM AND SUBSTRATE PROCESSING METHOD USING THE SAME

(71) Applicant: SAMSUNG ELECTRONICS CO., LTD., Suwon-si (KR)

(72) Inventor: HWAYOUNG LEE, Suwon-si (KR)

(21) Appl. No.: 18/967,349

(22) Filed: Dec. 3, 2024

(30) Foreign Application Priority Data
Jul. 1, 2024 (KR) 10-2024-0086069

(51) Int. Cl. H01L 21/66; H01L 21/78

(52) U.S. Cl. CPC H01L 22/12; H01L 21/78

(57) ABSTRACT

Provided are substrate processing systems and substrate processing methods. A substrate processing method includes grinding a back side of a substrate, attaching a die attach film to the substrate that is ground, and inspecting the substrate. Inspecting the substrate includes using a vision camera to inspect a surface of the substrate, and using an infrared laser device to inspect an interior of the substrate.

### CROSS-REFERENCE TO RELATED APPLICATION

This U.S. nonprovisional application claims priority under 35 U.S.C § 119 to Korean Patent Application No. 10-2024-0086069, filed on Jul. 1, 2024 in the Korean Intellectual Property Office, the disclosure of which is hereby incorporated by reference in its entirety.

### BACKGROUND

The present inventive concepts relate to a substrate processing system and a substrate processing method using the same, and more particularly, to a substrate processing system capable of identifying a position of a stealth dicing layer and a substrate processing method using the same.

A semiconductor device may be fabricated through various processes. For example, the semiconductor device may be manufactured through a photolithography process, an etching process, a deposition process, a plating process, and a packaging process performed on a substrate. In the packaging process, a wafer-level substrate may be divided into a plurality of dies. A stealth dicing process may be utilized to cut the substrate into a plurality of dies.

### SUMMARY

Some embodiments of the present inventive concepts provide a substrate processing system capable of automatically and accurately identifying a position of a stealth dicing layer in an interior of a substrate and a substrate processing method using the same.

Some embodiments of the present inventive concepts provide a substrate processing system capable of automatically identifying defects on a substrate surface and a substrate processing method using the same.

Objects of the present inventive concepts are not limited to those mentioned above, and other objects which have not been mentioned above will be clearly understood to those skilled in the art from the following description.

According to some embodiments of the present inventive concepts, a substrate processing method may include: grinding a back side of a substrate; attaching a die attach film to the substrate that is ground; and inspecting the substrate. Inspecting the substrate may include: using a vision camera to inspect a surface of the substrate; and using an infrared laser device to inspect an interior of the substrate.

According to some embodiments of the present inventive concepts, a substrate processing method may include: employing a stealth dicing process to form a stealth dicing layer in an interior of a substrate; grinding a back side of the substrate; inspecting the substrate; and cutting the substrate that is inspected. Inspecting the substrate may include: using an infrared laser device to irradiate an infrared laser toward the substrate; and identifying a position of the stealth dicing layer in the interior of the substrate.

According to some embodiments of the present inventive concepts, a substrate processing system may include: a grinding apparatus configured to grind a substrate; a substrate inspecting apparatus configured to inspect the substrate before cutting the substrate that is ground in the grinding apparatus; a film attaching apparatus configured to attach a die attach film to the substrate that is ground; and a vacuum chuck configured to move while vacuum-adsorbing the substrate. The grinding apparatus may include a grinding wheel configured to grind the substrate disposed on the vacuum chuck. The substrate inspecting apparatus may include: a vision camera configured to capture a surface of the substrate to inspect the surface of the substrate; and an infrared laser device configured to irradiate an infrared laser to inspect an interior of the substrate.

Details of other example embodiments are included in the description and drawings.

### BRIEF DESCRIPTION OF DRAWINGS

FIG. 1 illustrates a plan view showing a substrate processing system according to some embodiments of the present inventive concepts.

FIG. 2 illustrates a perspective view showing a substrate inspecting apparatus in a substrate processing system according to some embodiments of the present inventive concepts.

FIG. 3 illustrates a flow chart showing a substrate processing method according to some embodiments of the present inventive concepts.

FIGS. 4 to 9 illustrate diagrams showing a substrate processing method according to the flow chart of FIG. 3.

### DETAILED DESCRIPTION

The following will now describe some embodiments of the present inventive concepts with reference to the accompanying drawings. Like reference numerals may indicate like components throughout the description.

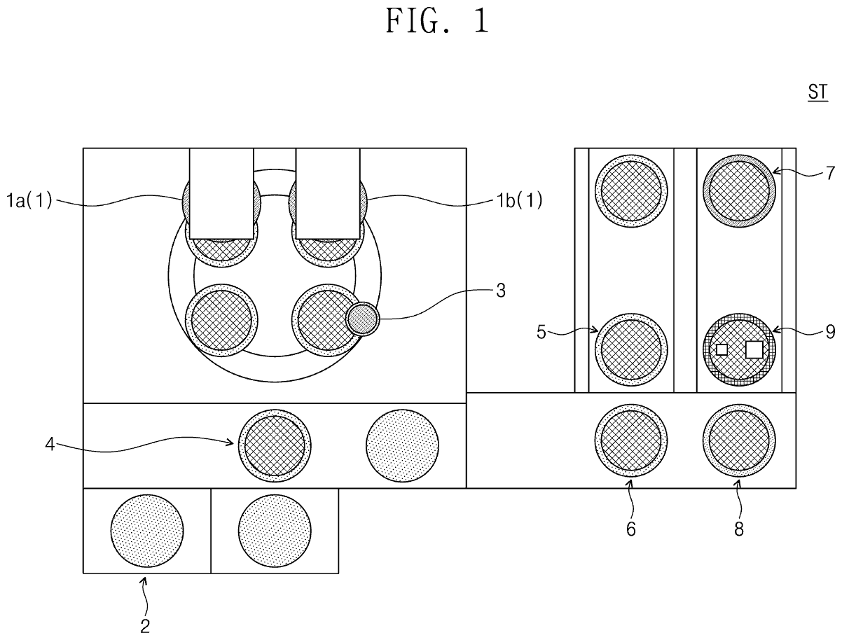

FIG. 1 illustrates a plan view showing a substrate processing system according to some embodiments of the present inventive concepts.

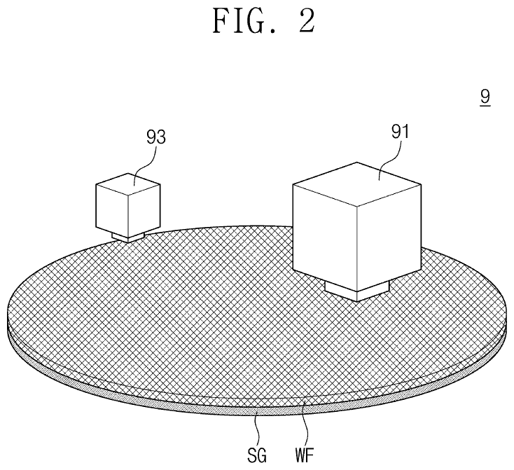

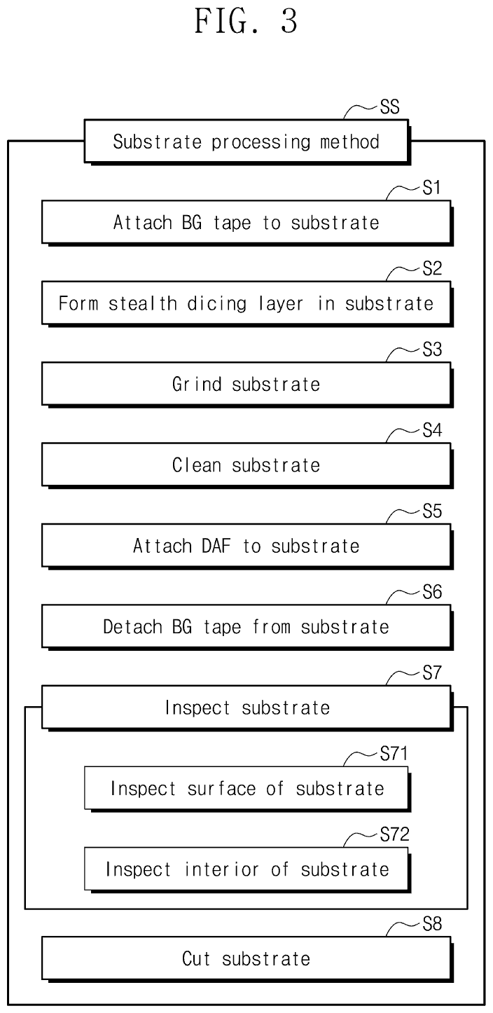

Referring to FIG. 1, a substrate processing system ST may be provided. The substrate processing system ST may be a system that processes a substrate. For example, the substrate processing system ST may be configured to allow a substrate to undergo a grinding process, a polishing process, a cleaning process, an inspecting process, or a cutting process. In this disclosure, the term “substrate” may refer to a wafer-level substrate. For example, a substrate may indicate a silicon (Si) wafer, but the present inventive concepts are not limited thereto. The substrate processing system ST may include a stealth dicing (SD) apparatus (see SD of FIG. 5), a (first) loading port 2, a vacuum chuck (see SG of FIG. 2), a transfer apparatus 4, a grinding apparatus 1, a substrate polishing apparatus 3, a second loading port 6, a film attaching apparatus 5, a detaching apparatus 7, a substrate inspecting apparatus 9, an unloading apparatus 8, and a substrate cutting apparatus (see, e.g., cutting operation in FIG. 3).

The SD apparatus (see SD of FIG. 5) may perform a stealth dicing process on a substrate. The SD apparatus SD may irradiate a laser to a substrate. For example, the SD apparatus SD may include a laser irradiating device. The SD apparatus SD may form a crack (see CR of FIG. 5) in an interior of a substrate. A laser (see SDL of FIG. 5) irradiated from the SD apparatus SD may form a stealth dicing layer in an interior of a substrate. A detailed description thereof will be provided below.

A substrate may be loaded on the loading port 2. A substrate that has passed through the SD apparatus SD may be disposed on the loading port 2. For example, a substrate may be loaded on the vacuum chuck (see SG of FIG. 2) disposed on the loading port 2. When a substrate is placed on the vacuum chuck SG on the loading port 2, the vacuum chuck SG may move while supporting the substrate. For example, the vacuum chuck SG by which a substrate is supported may move from the loading port 2 to a position below the grinding apparatus 1. A detailed description thereof will be provided below.

The vacuum chuck (see SG of FIG. 2) may support a substrate. The vacuum chuck SG, on which a substrate is disposed, may move between the loading port 2, the grinding apparatus 1, and the second loading port 6. The vacuum chuck SG may rigidly place a substrate on a certain position on the vacuum chuck SG. The vacuum chuck SG may be connected to a vacuum pump (not shown). The vacuum chuck SG may move while vacuum-adsorbing a substrate.

The transfer apparatus 4 may drive or transport the vacuum chuck SG on the loading port 2 to move to the grinding apparatus 1. Alternatively, the transfer apparatus 4 may drive or transport the vacuum chuck SG below the grinding apparatus 1 to move to the second loading port 6. The transfer apparatus 4 may include a transfer arm (not shown), but the present inventive concepts are not limited thereto.

The grinding apparatus 1 may grind a substrate. For example, the grinding apparatus 1 may be configured to grind a back side of a substrate. The grinding apparatus 1 may be a substrate lapping device. A substrate may be ground while being disposed on the vacuum chuck SG. The grinding apparatus 1 may extensively grind a back side of a substrate. The grinding apparatus 1 may include a grinding wheel to grind a substrate disposed on the vacuum chuck SG. One substrate processing system ST may be provided with a plurality of grinding apparatuses 1. For example, two grinding apparatuses 1 may be provided. In this sense, there may be provided a first grinding apparatus 1a and a second grinding apparatus 1b. A single grinding apparatus 1 will be described below in the interest of brevity and convenience.

The substrate polishing apparatus 3 may polish (or grind) a substrate. For example, the substrate polishing apparatus 3 may lightly polish a back side of a substrate. A quantity of a substrate polished by the substrate polishing apparatus 3 may be less than that of a substrate ground by the grinding apparatus 1. For example, the substrate polishing apparatus 3 may be a polishing device.

A ground substrate may be disposed on the second loading port 6. For example, a substrate released from the grinding apparatus 1 and/or the substrate polishing apparatus 3 may be disposed on the second loading port 6.

The film attaching apparatus 5 may attach a die attach film (DAF) to a substrate. For example, the film attaching apparatus 5 may attach a die attach film (DAF) to a substrate ground in the grinding apparatus 1 and/or the substrate polishing apparatus 3. A detailed description thereof will be provided below.

The detaching apparatus 7 may detach a back grinding (BG) tape from a substrate to which the BG tape is attached. For example, the detaching apparatus 7 may remove a BG tape attached to a front side of a substrate that is loaded through the second loading port 6. A detailed description thereof will be provided below.

The substrate inspecting apparatus 9 may inspect a substrate. For example, the substrate inspecting apparatus 9 may inspect a substrate before cutting the substrate that has passed through the SD apparatus (see SD of FIG. 5). The substrate inspecting apparatus 9 may inspect a surface and/or an interior of a substrate. In some embodiments, the substrate inspecting apparatus 9 may inspect a substrate before cutting the substrate that has been ground in the grinding apparatus 1. In this case, the substrate inspecting apparatus 9 may be positioned between the grinding apparatus 1 and the unloading apparatus 8. In some embodiments, the substrate inspecting apparatus 9 may inspect a substrate from which a back grinding (BG) tape is detached. In this case, the substrate inspecting apparatus 9 may be positioned between the detaching apparatus 7 and the unloading apparatus 8, as shown in FIG. 1. The present inventive concepts, however, are not limited thereto, and different from that shown in FIG. 1, the substrate inspecting apparatus 9 may be positioned between the loading port 2 and the grinding apparatus 1. Alternatively, a portion of the substrate inspecting apparatus 9 may be positioned between the loading port 2 and the grinding apparatus 1, and another portion of the substrate inspecting apparatus 9 may be positioned between the detaching apparatus 7 and the unloading apparatus 8. In this case, an internal inspection of a substrate may be performed before the substrate passes through the grinding apparatus 1, and a surface inspection of a substrate may be performed after the substrate passes through the detaching apparatus 7. For convenience and in the interest of brevity, the following will illustrate and describe an example where the substrate inspecting apparatus 9 is positioned between the detaching apparatus 7 and the unloading apparatus 8, and where the internal and surface inspections of the substrate are all performed after the substrate passes through the detaching apparatus 7. The substrate inspecting apparatus 9 will be further discussed in detail below.

The unloading apparatus 8 may load a substrate that has passed through the film attaching apparatus 5, the detaching apparatus 7, and/or the substrate inspecting apparatus 9. A substrate loaded on the unloading apparatus 8 may be transferred through an automated guided vehicle (AGV) to a substrate cutting apparatus.

The substrate cutting apparatus may cut a substrate. For example, the substrate cutting apparatus may cut a wafer-level substrate into a plurality of dies. The substrate cutting apparatus may cut, for example, a substrate to which a die attach film (DAF) is attached. For example, the substrate cutting apparatus may expand the DAF in all directions, and a wafer-level substrate attached on the DAF may be cut into a plurality of dies.

FIG. 2 illustrates a perspective view showing a substrate inspecting apparatus in a substrate processing system according to some embodiments of the present inventive concepts.

Referring to FIG. 2, the substrate inspecting apparatus 9 may include an infrared (IR) laser device 91 and a vision camera 93.

The IR laser device 91 may irradiate an IR laser toward a substrate WF. The IR laser irradiated from the IR laser device 91 may inspect an interior of the substrate WF. For example, the IR laser that is irradiated from the IR laser device 91 to an interior of the substrate WF may identify a position of a stealth dicing layer formed in the substrate WF. A detailed description thereof will be provided below.

The vision camera 93 may inspect a surface of the substrate WF. For example, the vision camera 93 may capture the surface of the substrate WF to detect cracks, sawing marks, or particles formed on the surface of the substrate WF. A detailed description thereof will be provided below.

The IR laser device 91 and/or the vision camera 93 may be movable in a horizontal direction. The substrate inspecting apparatus 9 may further include an inspection driving mechanism. While the IR laser device 91 and/or the vision camera 93 inspect the substrate WF, the inspection driving mechanism may drive the IR laser device 91 and/or the vision camera 93 to move in a horizontal direction. A detailed description thereof will be provided below.

FIG. 3 illustrates a flow chart showing a substrate processing method according to some embodiments of the present inventive concepts.

Referring to FIG. 3, a substrate processing method SS may be provided. The substrate processing method SS may be a way of processing a substrate by using the substrate processing system (see ST of FIG. 1) discussed with reference to FIGS. 1 and 2. The substrate processing method SS may include attaching a back grinding (BG) tape to a substrate (S1), forming a stealth dicing layer in the substrate (S2), grinding the substrate (S3), cleaning the substrate (S4), attaching a die attach film (DAF) to the substrate (S5), detaching the BG tape from the substrate (S6), inspecting the substrate (S7), and cutting the substrate (S8).

The inspecting of the substrate (S7) may include inspecting a surface of the substrate (S71) and inspecting an interior of the substrate (S72).

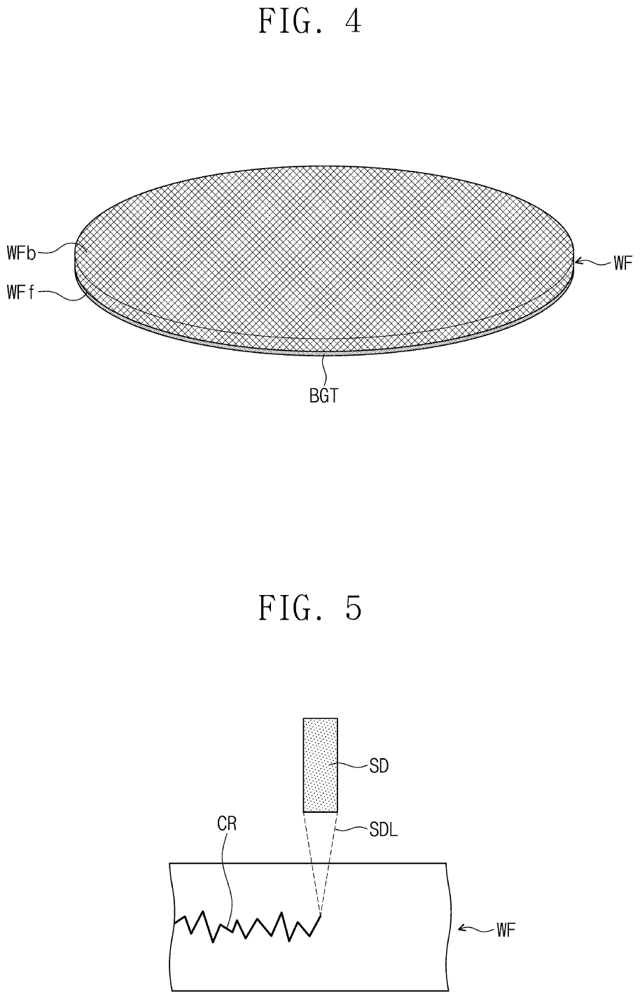

The substrate processing method SS will be discussed in detail below with reference to FIGS. 4 to 9.

FIGS. 4 to 9 illustrate diagrams showing a substrate processing method according to the flow chart of FIG. 3.

Referring to FIGS. 3 and 4, the attaching of the BG tape to the substrate (S1) may include attaching a back grinding tape BGT to a front side WFf of the substrate WF. The BG tape BGT attached to the front side WFf of the substrate WF may protect the front side WFf of the substrate WF during the grinding of the substrate WF. The attaching of the BG tape BGT to the substrate WF may be performed by an apparatus that is not shown in FIG. 1. The front side WFf of the substrate WF may refer to an active surface of the substrate WF. In a state where the BG tape BGT is attached to the front side WFf of the substrate WF, a back side WFb of the substrate WF may be exposed.

Referring to FIGS. 3 and 5, the forming of the stealth dicing layer in the substrate (S2) may include using a stealth dicing (SD) apparatus SD to form a crack CR in the substrate WF. The SD apparatus SD may irradiate a laser SDL to form the crack CR in the substrate WF. A layer having the crack CR formed in the substrate WF may be called a stealth dicing layer.

The aforementioned description and illustration are based on an example where the stealth dicing process is performed after the attachment of the BG tape BGT to the substrate WF, but the present inventive concepts are not limited thereto. For example, after the stealth dicing process of the substrate WF, the BG tape BGT may be attached to the front side (see WFf of FIG. 4) of the substrate WF.

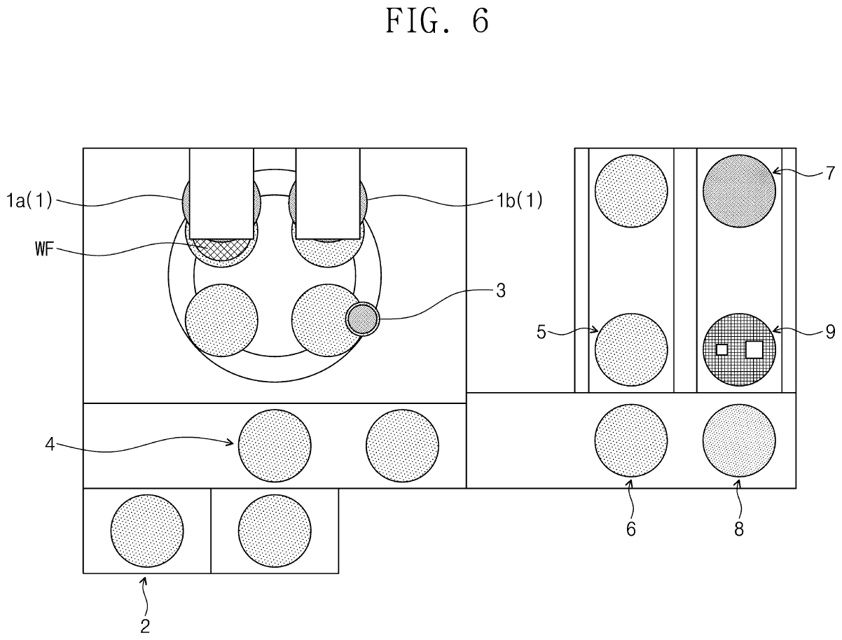

Referring to FIG. 6, the substrate WF that has passed through the SD apparatus (see SD of FIG. 5) may be loaded on the loading port 2. The substrate WF loaded on the vacuum chuck (see SG of FIG. 2) on the loading port 2 may move, together with the vacuum chuck SG, underneath the grinding apparatus 1.

Referring to FIGS. 3 and 6, the grinding of the substrate (S3) may include grinding the back side (see WFb of FIG. 4) of the substrate WF. For example, the grinding apparatus 1 that rotates may grind the back side WFb of the substrate WF, while being in contact with the back side WFb of the substrate WF. The substrate WF may be ground while being held on the vacuum chuck (see SG of FIG. 2). Therefore, the thickness of the substrate WF may be reduced. The substrate polishing apparatus 3 may selectively polish the substrate WF that has passed through the grinding apparatus 1.

Referring to FIG. 3, the cleaning of the substrate (S4) may include cleaning the substrate WF that is ground. The substrate processing system (see ST of FIG. 6) may further include a substrate cleaning apparatus.

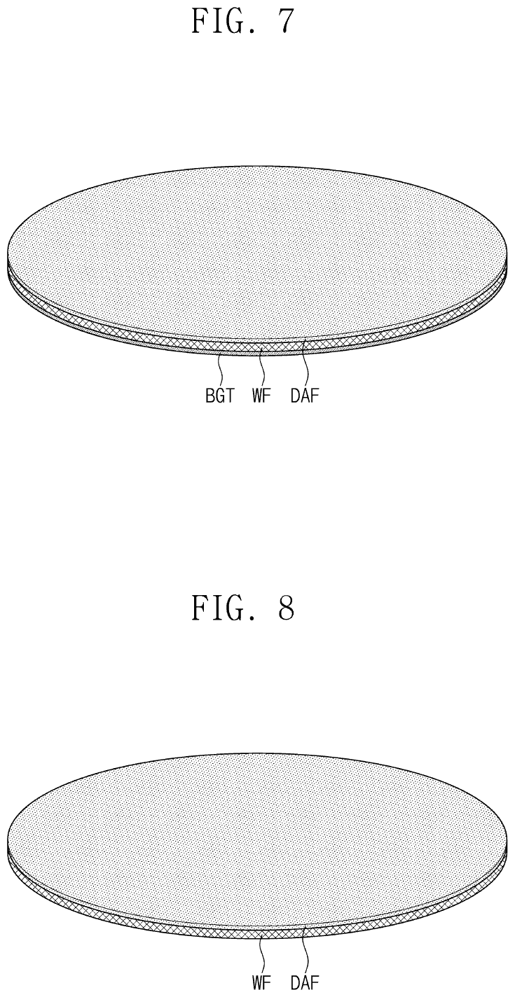

Referring to FIGS. 3 and 7, the attaching of a DAF to the substrate (S5) may include a die attach film (DAF) may be attached to the substrate WF in the film attaching apparatus (see 5 of FIG. 6). For example, the DAF may be attached to the back side (see WFb of FIG. 4) of the substrate WF. The DAF may be attached to a side of the substrate WF opposite to another side of the substrate WF to which the BG tape BGT is attached.

Referring to FIGS. 3 and 8, the detaching of the BG tape from the substrate (S6) may include allowing the detaching apparatus 7 to detach the BG tape BGT from the substrate WF that is ground.

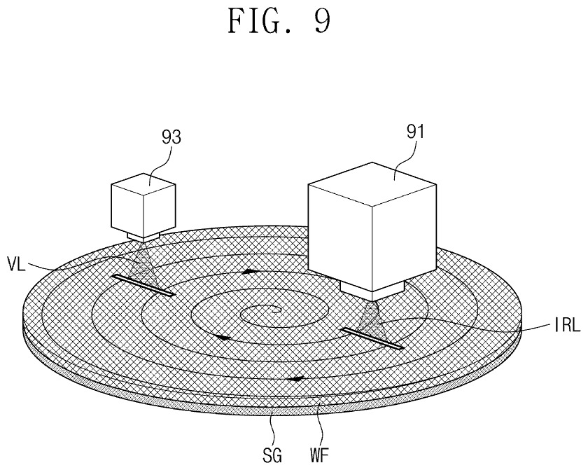

Referring to FIGS. 3 and 9, the inspecting of the substrate (S7) may include allowing the vacuum chuck SG that supports the substrate WF to move underneath the vision camera 93 and the IR laser device 91, and using the vision camera 93 to inspect a surface of the substrate WF (S71), and using the IR laser device 91 to inspect an interior of the substrate WF (S72).

The using of the vision camera 93 to inspect the surface of the substrate WF may include detecting cracks, sawing marks, or particles formed on the surface of the substrate WF held on the vacuum chuck SG. The substrate WF may rotate while the vision camera 93 captures image(s) VL of the substrate WF. In addition, the vision camera 93 may move in a horizontal direction while the vision camera 93 captures the substrate WF. An entire region of the substrate WF may thus be inspected.

The using of the IR laser device 91 to inspect the interior of the substrate WF may include allowing the IR laser device 91 to irradiate an IR laser IRL toward the substrate WF. Therefore, it may be possible to identify a position of the stealth dicing layer formed in the substrate WF. The substrate WF may rotate while the IR laser device 91 irradiates the IR laser IRL toward the substrate WF. In addition, the substrate WF may move in a horizontal direction while the IR laser device 91 irradiates the IR laser IRL toward the substrate WF. An entire region of the substrate WF may thus be inspected. The substrate WF that is inspected may be unloaded by the unloading apparatus (see 8 of FIG. 6).

Referring to FIG. 3, the cutting of the substrate (S8) may include cutting the substrate WF that is inspected. For example, the DAF attached to the substrate WF may expand in all directions such that a wafer-level substrate attached on the DAF may be divided into a plurality of dies.

According to a substrate processing system and a substrate processing method using the same in accordance with some embodiments of the present inventive concepts, before a substrate is cut, it may be possible to automatically identify a position of a stealth dicing layer formed in the substrate. Therefore, it may not be necessary to manually inspect whether or not defects exist in the stealth dicing layer. Accordingly, a process may be promptly performed.

According to a substrate processing system and a substrate processing method using the same in accordance with some embodiments of the present inventive concepts, as an IR laser may be used to inspect a substrate, an interior of the substrate may be promptly inspected without cutting the substrate.

According to a substrate processing system and a substrate processing method using the same in accordance with some embodiments of the present inventive concepts, defects formed on a surface of a substrate may be automatically identified during a grinding process. Thus, it may not be necessary to manually execute an inspection. Accordingly, a process may be promptly performed.

According to a substrate processing system and a substrate processing method using the same in accordance with some embodiments of the present inventive concepts, defects of a stealth dicing layer formed in an interior of a substrate whose thickness is reduced after a grinding process for the substrate may be inspected to achieve an accurate inspection.

According to a substrate processing system and a substrate processing method using the same in accordance with some embodiments of the present inventive concepts, as a substrate is inspected after a back grinding (BG) tape is detached from the substrate, an accurate substrate inspection may be accomplished.

According to a substrate processing system and a substrate processing method using the same in accordance with some embodiments of the present inventive concepts, a position of a stealth dicing layer in an interior of a substrate may be automatically and accurately identified.

According to substrate processing system and a substrate processing method using the same in accordance with some embodiments of the present inventive concepts, defects on a substrate surface may be automatically identified.

Effects of the present inventive concepts are not limited to the mentioned above, other effects which have not been mentioned above will be clearly understood to those skilled in the art from the foregoing description.

Although the present inventive concepts have been described in connection with some embodiments of the present inventive concepts illustrated in the accompanying drawings, it will be understood to those skilled in the art that various changes and modifications may be made without departing from the technical spirit and essential feature of the present inventive concepts. It therefore will be understood that the example embodiments described above are illustrative but not limitative in all aspects.

What is claimed is:

1. A substrate processing method, comprising:
grinding a back side of a substrate;
attaching a die attach film to the substrate that is ground; and
inspecting the substrate,
wherein inspecting the substrate includes:
using a vision camera to inspect a surface of the substrate; and
using an infrared laser device to inspect an interior of the substrate.

2. The substrate processing method of claim 1, wherein using the infrared laser device to inspect the interior of the substrate includes:
irradiating an infrared laser toward the substrate; and
identifying a position of a stealth dicing layer formed in the interior of the substrate.

3. The substrate processing method of claim 1, wherein using the vision camera to inspect the surface of the substrate includes detecting a crack, a sawing mark, or a particle formed on the surface of the substrate.

4. The substrate processing method of claim 1, further comprising detaching a back grinding tape from the substrate that is ground.

5. The substrate processing method of claim 4, wherein inspecting the substrate is performed after detaching the back grinding tape from the substrate.

6. The substrate processing method of claim 1, wherein using the vision camera to inspect the surface of the substrate includes:
rotating the substrate while the vision camera captures the substrate; and
moving the vision camera in a horizontal direction while the vision camera captures the substrate,
wherein using the infrared laser device to inspect the interior of the substrate includes:
rotating the substrate while the infrared laser device irradiates an infrared laser toward the substrate; and
moving the infrared laser device in the horizontal direction while the infrared laser device irradiates the infrared laser toward the substrate.

7. The substrate processing method of claim 1, wherein
grinding the back side of the substrate includes grinding the substrate while the substrate is held on a vacuum chuck, and
inspecting the substrate includes moving the vacuum chuck underneath the vision camera and the infrared laser device in a state where the vacuum chuck holds the substrate.

8. The substrate processing method of claim 1, further comprising cleaning the substrate that is ground before inspecting the substrate.

9. A substrate processing method, comprising:
employing a stealth dicing process to form a stealth dicing layer in an interior of a substrate;
grinding a back side of the substrate;
inspecting the substrate; and
cutting the substrate that is inspected,
wherein inspecting the substrate includes:
using an infrared laser device to irradiate an infrared laser toward the substrate; and
identifying a position of the stealth dicing layer in the interior of the substrate.

10. The substrate processing method of claim 9, wherein inspecting the substrate includes using a vision camera to detect a crack, a sawing mark, or a particle formed on a surface of the substrate.

11. The substrate processing method of claim 9, further comprising attaching a die attach film to the substrate before cutting the substrate.

12. The substrate processing method of claim 9, wherein grinding the back side of the substrate includes using a grinding wheel to grind the substrate held on a vacuum chuck.

13. The substrate processing method of claim 9, wherein using the infrared laser device to irradiate the infrared laser toward the substrate includes:
rotating the substrate while the infrared laser device irradiates the infrared laser toward the substrate; and
moving the infrared laser device in a horizontal direction while the infrared laser device irradiates the infrared laser toward the substrate.

14. A substrate processing system, comprising:
a grinding apparatus configured to grind a substrate;
a substrate inspecting apparatus configured to inspect the substrate before cutting the substrate that is ground in the grinding apparatus;
a film attaching apparatus configured to attach a die attach film to the substrate that is ground; and
a vacuum chuck configured to move while vacuum-adsorbing the substrate,
wherein the grinding apparatus includes a grinding wheel configured to grind the substrate disposed on the vacuum chuck,
wherein the substrate inspecting apparatus includes:
a vision camera configured to capture a surface of the substrate to inspect the surface of the substrate; and
an infrared laser device configured to irradiate an infrared laser to inspect an interior of the substrate.

15. The substrate processing system of claim 14, wherein the grinding apparatus comprises first and second grinding apparatuses.

16. The substrate processing system of claim 14, further comprising a substrate polishing apparatus between the grinding apparatus and the film attaching apparatus.

17. The substrate processing system of claim 14, wherein the substrate inspecting apparatus further includes an inspection driving apparatus configured to drive the vision camera and the infrared laser device to move in a horizontal direction.

18. The substrate processing system of claim 14, further comprising a substrate cutting apparatus configured to cut the substrate to which a die attach film is attached.

19. The substrate processing system of claim 14, further comprising a detaching apparatus configured to detach a back grinding tape attached to the substrate.

20. The substrate processing system of claim 14, further comprising a stealth dicing apparatus configured to form a stealth dicing layer in the interior of the substrate.
